(19) United States
(12) Patent Application Publication
(10) Pub. No.: US 2020/0059092 A1
(43) Pub. Date: Feb. 20, 2020

(54) ESD PROTECTION CIRCUIT WITH REDUCED PARASITE CAPACITANCE AND METHOD FOR REDUCING ESD PARASITE CAPACITANCE

(71) Applicant: SUPERC-TOUCH CORPORATION, New Taipei City (TW)

(72) Inventors: Hsiang-Yu LEE, New Taipei City (TW); Shang CHIN, New Taipei City (TW); Ping-Tsun LIN, New Taipei City (TW); Chia-Cheng LEI, New Taipei City (TW); Yu-Chieh LIN, New Taipei City (TW)

(21) Appl. No.: 16/105,321

(22) Filed: Aug. 20, 2018

(51) Int. Cl. H02H 9/04; H01L 27/02; G06F 3/041

(52) U.S. Cl. CPC H02H 9/046; G06F 3/041; H01L 27/0266; H01L 27/0255

(57) ABSTRACT

An ESD protection circuit includes at least two unidirectional conduction units arranged between an IO node of an integrated circuit and a positive voltage node, where a first connection node is between the at least two unidirectional conduction units; at least two unidirectional conduction units arranged between the IO node and a negative voltage node, where a second connection node is between the at least two unidirectional conduction units; and a voltage tracking circuit. The input of the voltage tracking circuit is electrically connected to the IO node and the output of the voltage tracking circuit is electrically connected to at least one of the first connection end and the second connection end. By reducing the voltage difference between the IO node and the first connection end or between the IO node and the second connection end, the parasite capacitance associated with the unidirectional conduction unit can be reduced.

### BACKGROUND OF THE INVENTION

### Field of the Invention

The present invention relates to a circuit and a method, more particularly to an ESD protection circuit with reduced parasite capacitance and method for reducing ESD parasite capacitance.

### Description of Related Art

The touch control technology has fast development as the mobile electronic devices become popular. As a result, the conventional touch screen operation cannot meet the requirement for hovering control. The optical hovering control consumes considerable electric power and the lens used for the optical hovering control is against the trend for frameless and all screen display. The capacitance-type hovering control scheme is most suitable for the current mobile electronic devices. However, it is extremely difficult to precisely detect the minute capacitance change caused by hovering object. The stray capacitance present on the connection path between the touch sensing electrode and the touch control IC is detrimental for capacitance sensing. The parasite capacitance from the electrostatic discharge (ESD) protection circuit, which is generally arranged on the IO node of the touch control IC, is even harmful for capacitance sensing. The present invention is aimed to provide an ESD protection circuit with reduced parasite capacitance and method for reducing ESD parasite capacitance, thus enable the mobile electronic device to precise detect minute capacitance change.

FIG. 8 is a sectional view of a prior art capacitance-type touch sensing apparatus, the capacitance-type touch sensing apparatus comprises a substrate 102A, a touch control integrated circuit (IC) 100A, a protection layer 140A and a display device 150A. The touch control IC 100A is arranged on the substrate 102A and the substrate 102A has a sensing area with a plurality of touch sensing electrodes 110A and a plurality of lead-out wires 130A. The touch sensing electrodes 110A are arranged on the face of the substrate 102A near to user finger and are electrically connected to the conductive pads PD of the touch control IC 100A, where the conductive pad PD can also be referred to as IO node and hereinafter the IO node is used to describe the conductive pad. The conventional capacitance-type touch sensing apparatus generally uses the protection layer 140A to protect the touch sensing electrodes 110A and the lead-out wires 130A to prevent from the damage of the touch sensing electrodes 110A and the lead-out wires 130A due to finger scratch, where the protection layer 140A adopts glass film or plastic film with high dielectric constant. During hovering control operation, a touch capacitance constituted by C1 in series with C2 is present between user finger and the touch sensing electrode 110A. During touch control operation, only touch capacitance of C1 is present between user finger and the touch sensing electrode 110A. When performing hovering control operation, the capacitance C2 is much less than the capacitance C1 because the dielectric constant of the air is much less than that of the glass film or plastic film and the distance between user finger and the protection layer 140A is much larger than the thickness of the protection layer 140A. Therefore, the touch capacitance constituted by C1 in series with C2 is approximately equal to the capacitance C2. Due to above reasons, the capacitance C2 is very small such that the hovering control operation is difficult to precisely conduct if interference from the parasite capacitance cannot be prevented.

FIG. 1A shows a related art ESD protection circuit 10A, which comprises a positive voltage node (also referred to as power end) Vd, a negative voltage node (also referred to as ground end) Vs, a diode Dp1 connected between the positive voltage node Vd and the IO node (namely, the conductive pad) PD, a diode Dn1 connected between the negative voltage node Vs and the IO node PD. FIG. 1B shows a semiconductor counterpart corresponding to that of FIG. 1A, as shown in this figure, the diode Dp1 can be, for example, implemented by MOS transistor Qp1. The gate of the MOS (such as PMOS) transistor Qp1 is connected to the drain thereof to implement the diode Dp1, where current flows from the source to the drain. The gate of the MOS (such as NMOS) transistor Qn1 is connected to the drain thereof to implement the diode Dn1, where current flows from the drain to the source.

However, in above related art ESD protection circuit 10A, as shown in FIG. 1C, parasite capacitance Cp1 is present between the positive voltage node Vd and the IO node PD, and parasite capacitance Cn1 is present between the negative voltage node Vs and the IO node PD.

With reference also to FIGS. 1D and 1E, those figures respectively show the semiconductor structures corresponding to upper portion and lower portion of FIG. 1C. As shown in FIG. 1D, if the related art ESD protection circuit 10A is implemented by semiconductor structure, parasite capacitance Cp1 is present between the p+ region and n+ region in the n well, which are corresponding to anode and cathode of the diode Dp1. Similarly, as shown in FIG. 1E, parasite capacitance Cn1 is present between the p+ region and n+ region in the p substrate, which are corresponding to anode and cathode of the diode Dn1.

FIG. 1F shows the schematic view of MOS implemented diode of FIG. 1B with parasite capacitance. Similarly, as shown FIG. 1F, parasite capacitance Cp1 is present between the positive voltage node Vd and the IO node PD, and parasite capacitance Cn1 is present between the negative voltage node Vs and the IO node PD. With reference also to FIGS. 1G and 1H, those figures respectively show the semiconductor structures corresponding to upper portion and lower portion of FIG. 1F. As shown in FIG. 1G, if the related art ESD protection circuit 10A is implemented by semiconductor structure, parasite capacitance Cp1 is present between the p+ region and n+ region in the n well, which are corresponding to the source of the PMOS transistor Qp1 and the short-circuited connection point between the gate and the drain thereof. Similarly, as shown in FIG. 1H, parasite capacitance Cn1 is present between the p+ region and n+ region in the p substrate, which are corresponding to short-circuited connection point between the gate and the drain thereof, and the source of the NMOS transistor Qn1.

FIGS. 2A and 2B shows another related art ESD protection circuits 10A. The related art ESD protection circuit 10A shown in FIG. 2A is similar to that shown in FIG. 1A, however, additional unidirectional conduction unit, such as diode Dp2 or diode Dn2, is provided between the positive voltage node Vd and the IO node PD, and between the negative voltage node Vs and the IO node PD. The related art ESD protection circuit 10A shown in FIG. 2B is similar to that shown in FIG. 1B, however, additional unidirectional conduction unit, such as MOS transistor Qp2 or MOS transistor Qn2, is provided between the positive voltage node Vd and the IO node PD, and between the negative voltage node Vs and the IO node PD. Similar, in above ESD protection circuit 10A of FIG. 2A, as shown in FIG. 2C, parasite capacitances Cp1 and Cp2 are present between the positive voltage node Vd and the IO node PD, and parasite capacitances Cn1 and Cn2 are present between the negative voltage node Vs and the IO node PD. With reference also to FIGS. 2D and 2E, those figures respectively show the semiconductor structures corresponding to upper portion and lower portion of FIG. 2C. As shown in FIG. 2D, if the related art ESD protection circuit 10A is implemented by semiconductor structure, parasite capacitances Cp1 and Cp2 are present between the p+ region and the n+ region in the corresponding n well, which are corresponding to anode and cathode of the diodes Dp1, Dp2. Similarly, as shown in FIG. 2E, parasite capacitances Cn1 and Cn2 are present between the p+ region and the n+ region in the corresponding p substrate, which are corresponding to anode and cathode of the diodes Dn1, Dn2.

With reference again to FIG. 8, the parasite capacitance in the related art ESD protection circuits 10A is around several pF and the parasite capacitance is present at the IO node PD of the touch control IC 100A. Moreover, the hovering control capacitance for a touching object (such as user finger) hovering on the touch sensing electrode 110A is far less than that of parasite capacitance (for example, less than one percent of the parasite capacitance). The sensibility and accuracy of the hovering control apparatus will be seriously influenced if the impact of the parasite capacitance cannot be minimized.

### SUMMARY OF THE INVENTION

It is an object of the present invention to provide an ESD protection circuit with reduced parasite capacitance and method for reducing ESD parasite capacitance. The ESD protection circuit can be advantageously used in electronic device for sensing minute amount of capacitance change, such as electronic device with touch sensing function or hovering sensing function, thus greatly reduces parasite capacitance.

Accordingly, the present invention provides an electrostatic discharge (ESD) protection circuit with reduced parasite capacitance. The ESD protection circuit is electrically connected to an IO node of an integrated circuit and comprises: at least two unidirectional conduction units arranged between the IO node and a positive voltage node, wherein a first connection node is between the at least two unidirectional conduction units; at least two unidirectional conduction units arranged between the IO node and a negative voltage node, wherein a second connection node is between the at least two unidirectional conduction units; and a voltage tracking circuit, an input of the voltage tracking circuit connected to the IO node and an output of the voltage tracking circuit electrically connected to at least one of the first connection node and the second connection node such that the IO node and the first connection node have substantially the same voltage or the IO node and the second connection node have substantially the same voltage.

Accordingly, the present invention provides a method for reducing electrostatic discharge (ESD) parasite capacitance. The method comprises: (a) providing an ESD protection circuit for an IO node of an integrated circuit, the ESD protection circuit comprising: at least two unidirectional conduction units arranged between the IO node and a positive voltage node, wherein a first connection node is between the at least two unidirectional conduction units; at least two unidirectional conduction units arranged between the IO node and a negative voltage node, wherein a second connection node is between the at least two unidirectional conduction units; (b) providing a voltage tracking circuit, connecting an input of the voltage tracking circuit to the IO node and connecting an output of the voltage tracking circuit to at least one of the first connection node and the second connection node such that the IO node and the first connection node have substantially the same voltage or the IO node and the second connection node have substantially the same voltage.

The ESD protection circuit with reduced parasite capacitance and method for reducing ESD parasite capacitance according to the present can reduce the parasite capacitance of the unidirectional conduction unit (such as diode or MOS transistor) by reducing the voltage difference between two terminals of the unidirectional conduction unit. The parasite capacitance associated with the ESD protection circuit can be greatly reduced. Therefore, the ESD protection circuit according to the present invention can be advantageously used in electronic device for sensing minute amount of capacitance change, such as electronic device with touch sensing function or hovering sensing function, thus greatly enhance the accuracy for touch sensing operation or hovering sensing operation.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1A shows a related art ESD protection circuit.

FIG. 1B shows another related art ESD protection circuit.

FIG. 1C shows the parasite capacitance present in circuit of FIG. 1A.

FIG. 1D shows the semiconductor structures corresponding to upper portion of FIG. 1C.

FIG. 1E shows the semiconductor structures corresponding to lower portion of FIG. 1C.

FIG. 1F shows the parasite capacitance present in circuit of FIG. 1B.

FIG. 1G shows the semiconductor structures corresponding to upper portion of FIG. 1F.

FIG. 1H shows the semiconductor structures corresponding to lower portion of FIG. 1F.

FIG. 2A shows still another related art ESD protection circuit.

FIG. 2B shows still another related art ESD protection circuit.

FIG. 2C shows the parasite capacitance present in circuit of FIG. 2A.

FIG. 2D shows the semiconductor structures corresponding to upper portion of FIG. 2C.

FIG. 2E shows the semiconductor structures corresponding to lower portion of FIG. 2C.

FIG. 3A shows a circuit diagram for the ESD protection circuit with reduced parasite capacitance according to an embodiment of the present invention.

FIG. 3B shows a circuit diagram for the ESD protection circuit with reduced parasite capacitance according to another embodiment of the present invention.

FIG. 3C shows a circuit diagram for the ESD protection circuit with reduced parasite capacitance according to still another embodiment of the present invention.

FIG. 4A shows the parasite capacitance present in circuit of FIG. 3A.

FIG. 4B shows the semiconductor structures corresponding to upper portion of FIG. 4A.

FIG. 4C shows the semiconductor structures corresponding to lower portion of FIG. 4A.

FIG. 5 shows a circuit diagram for the ESD protection circuit with reduced parasite capacitance according to still another embodiment of the present invention.

FIG. 6A shows the parasite capacitance present in circuit of FIG. 5.

FIG. 6B shows the semiconductor structures corresponding to upper portion of FIG. 6A.

FIG. 6C shows the semiconductor structures corresponding to lower portion of FIG. 6A.

FIG. 7A shows a circuit diagram for the ESD protection circuit with reduced parasite capacitance according to still another embodiment of the present invention.

FIG. 7B is a more detailed circuit diagram corresponding to FIG. 7A.

FIG. 8 is a sectional view of a prior art capacitance-type touch sensing apparatus.

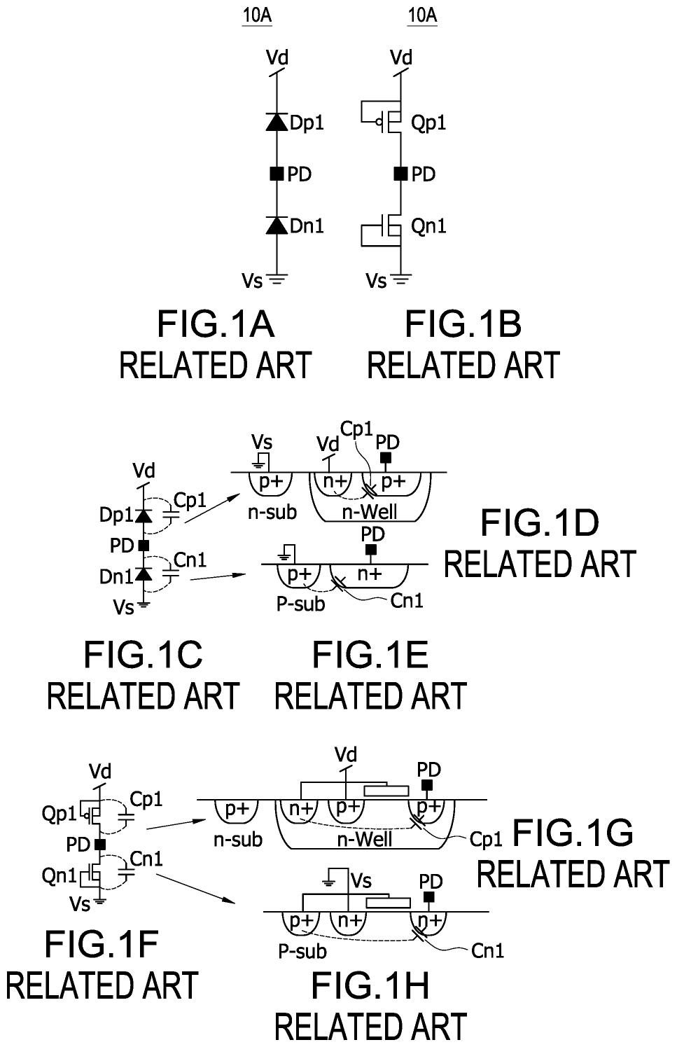

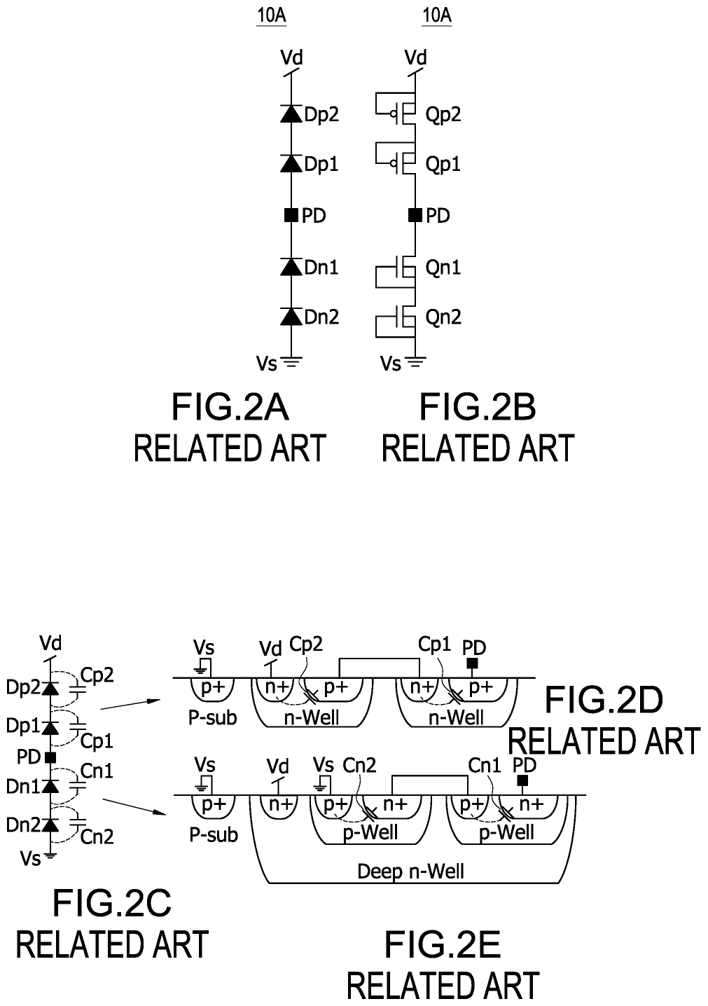

### DETAILED DESCRIPTION OF THE INVENTION

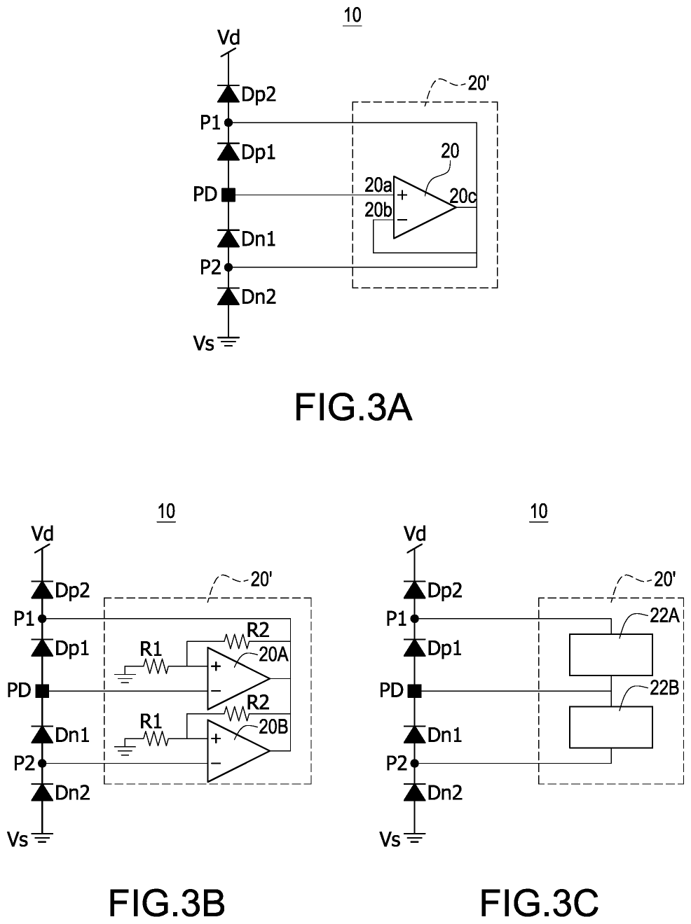

FIG. 3A shows a circuit diagram for the ESD protection circuit 10 with reduced parasite capacitance according to an embodiment of the present invention. The ESD protection circuit 10 according to the present invention can be advantageously used in electronic device for sensing minute amount of capacitance change, such as electronic device with touch sensing function or hovering sensing function. The ESD protection circuit 10 according to the present invention has reduced parasite capacitance such that it will prevent the influence of the parasite capacitance during touch sensing operation or hovering sensing operation. The ESD protection circuit 10 shown in FIG. 3A comprises at least two unidirectional conduction units Dp1, Dp2 arranged between an IO node PD of an integrated circuit and a positive voltage node Vd, at least two unidirectional conduction units Dn1, Dn2 arranged between the IO node and a negative voltage node Vs, and a voltage tracking circuit 20′.

As shown in this figure, the two unidirectional conduction units Dp1, Dp2 are for example two diodes Dp1, Dp2 in series connection and along the same polarity direction. Namely, the two diodes Dp1, Dp2 are in series connection between the positive voltage node Vd (higher level end) and the IO node PD (lower level end) for reverse bias, and a first connection node P1 is arranged between the two diodes Dp1, Dp2. The two unidirectional conduction units Dn1, Dn2 are for example two diodes Dn1, Dn2 in series connection and along the same polarity direction. Namely, the two diodes Dn1, Dn2 are in series connection between the IO node PD (higher level end) and the negative voltage node Vs (lower level end) for reverse bias, and a second connection node P2 is arranged between the two diodes Dn1, Dn2.

The voltage tracking circuit 20′ is for example, a voltage follower implemented by operational amplifier and comprises an operational amplifier 20. The operational amplifier 20 has a non-inverting input 20a, an inverting input 20b and an output end 20c. More particularly, as shown in FIG. 3A, the non-inverting input 20a of the operational amplifier 20 is electrically connected to the IO node PD, the inverting input 20b of the operational amplifier 20 is electrically connected to the second connection node P2, and the output end 20c of the operational amplifier 20 is electrically connected to the inverting input 20b to form the voltage follower. Moreover, the output end 20c of the operational amplifier 20 is also electrically connected to the first connection node P1 and the second connection node P2. Due to the virtual ground between the non-inverting input 20a and inverting input 20b of the operational amplifier 20, the voltage at the IO node PD (connected to the non-inverting input 20a of the operational amplifier 20 and corresponding to the anode of the diode Dn1) and the voltage at the second connection node P2 (connected to the inverting input 20b of the operational amplifier 20 and corresponding to the cathode of the diode Dn1) are substantially the same. Therefore, the diode Dn1 has substantially no voltage difference between the anode and cathode thereof and there is substantially no parasite capacitance across the diode Dn1. Similarly, the voltage at the first connection node P1 (corresponding to the cathode of the diode Dp1) and the voltage at the IO node PD (corresponding to the anode of the diode Dp1) are substantially the same. Therefore, the diode Dp1 has substantially no voltage difference between the anode and cathode thereof and there is substantially no parasite capacitance across the diode Dp1.

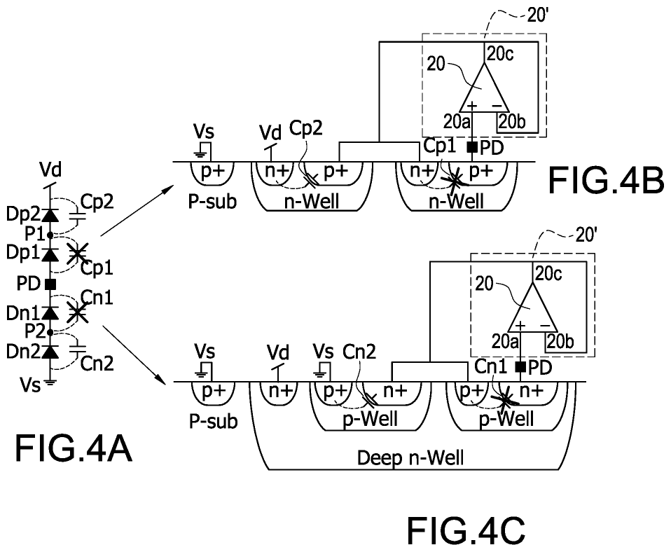

FIG. 4A is a schematic diagram showing the change of parasite capacitance in the ESD protection circuit 10 after the voltage tracking operation of the voltage tracking circuit 20′. Besides, FIGS. 4B and 4C respectively shows the semiconductor structures corresponding to upper portion and lower portion of FIG. 4A. As shown in FIG. 4A, due to the voltage tracking operation of the voltage tracking circuit 20′, the diode Dp1 has substantially no voltage difference between the anode and cathode (namely, between the IO node PD and the first connection node P1) thereof; and accordingly, there is substantially no or nearly no parasite capacitance across the diode Dp1. Besides, due to the voltage tracking operation of the voltage tracking circuit 20′, the diode Dn1 has substantially no voltage difference between the anode and cathode (namely, between the second connection node P2 and the IO node PD) thereof; and accordingly, there is substantially no or nearly no parasite capacitance across the diode Dn1. As clearly shown in FIG. 4A, a plurality of diodes Dp1, Dp2 are serially connected between the positive voltage node Vd and the IO node PD and are reversely biased. Namely, the parasite capacitances Cp1, Cp2 of those diodes Dp1, Dp2 are also serially connected. If the capacitance of the parasite capacitance Cp1 is zero or nearly zero, the equivalent capacitance of the serially connected parasite capacitances Cp1, Cp2 is also zero or nearly zero. Besides, as also clearly shown in FIG. 4A, a plurality of diodes Dn1, Dn2 are serially connected between the IO node PD and the negative voltage node Vs and are reversely biased. Namely, the parasite capacitances Cn1, Cn2 of those diodes Dn1, Dn2 are also serially connected. If the capacitance of the parasite capacitance Cn1 is zero or nearly zero, the equivalent capacitance of the serially connected parasite capacitances Cn1, Cn2 is also zero or nearly zero. In other word, the ESD protection circuit 10 according to the present invention can greatly reduce the parasite capacitance thereof. Besides, even though FIG. 4A shows that two diodes Dp1 and Dp2 are serially connected between positive voltage node Vd and the IO node PD and two diodes Dn1 and Dn2 are serially connected between IO node PD and the negative voltage node Vs; according to the concept of the present invention, more diodes can be serially connected between positive voltage node Vd and the IO node PD, and/or more diodes can be serially connected between IO node PD and the negative voltage node Vs. The equivalent capacitance of the multiple serially connected parasite capacitances is zero or nearly zero when one of the capacitances in the series is zero or nearly zero. Therefore, the ESD protection circuit 10 according to the present invention can be advantageously used in electronic device for sensing minute amount of capacitance change, such as electronic device with touch sensing function or hovering sensing function. The ESD protection circuit 10 according to the present invention not only provides ESD protection but also greatly reduces parasite capacitance.

FIG. 3B shows a circuit diagram for the ESD protection circuit 10 with reduced parasite capacitance according to another embodiment of the present invention. The ESD protection circuit 10 shown in FIG. 3B comprises at least two unidirectional conduction units Dp1, Dp2 arranged between a positive voltage node Vd and an IO node PD of an integrated circuit, at least two unidirectional conduction units Dn1, Dn2 arranged between the IO node and a negative voltage node Vs, and a voltage tracking circuit 20′. As shown in this figure, the two unidirectional conduction units Dp1, Dp2 are for example two diodes Dp1, Dp2 in series connection and along the same polarity direction. Namely, the two diodes Dp1, Dp2 are in series connection between the positive voltage node Vd and the IO node PD for reverse bias, and a first connection node P1 is arranged between the two diodes Dp1, Dp2. The two unidirectional conduction units Dn1, Dn2 are for example two diodes Dn1, Dn2 in series connection and along the same polarity direction. Namely, the two diodes Dn1, Dn2 are in series connection between the IO node PD and the negative voltage node Vs for reverse bias, and a second connection node P2 is arranged between the two diodes Dn1, Dn2.

Moreover, the voltage tracking circuit 20′ comprises a first amplifier circuit 20A arranged between the IO node PD and the first connection node P1. The first amplifier circuit 20A is, for example, a non-inverting amplifier circuit composed of operational amplifier with gain larger than 1. For example, the gain (1+(R2/R1)) of the first amplifier circuit 20A is larger than 1 and smaller than 1.1, namely, 1<(V_{P1}/V_{PD})<1.1. By the first amplifier circuit 20A, the diode Dp1 can be kept to be reversely biased and the voltage difference between the anode and the cathode thereof is nearly zero such that the parasite capacitance of the diode Dp1 can be greatly reduced. Besides, the voltage tracking circuit 20′ further comprises a second amplifier circuit 20B arranged between the IO node PD and the second connection node P2. The second amplifier circuit 20B is, for example, a non-inverting amplifier circuit composed of operational amplifier with gain larger than 1. For example, the gain (1+(R2/R1)) of the second amplifier circuit 20B is larger than 1 and smaller than 1.1, namely, 1<(V_{PD}/V_{P2})<1.1. By the second amplifier circuit 20B, the diode Dn1 can be kept to be reversely biased and the voltage difference between the anode and the cathode thereof is nearly zero such that the parasite capacitance of the diode Dn1 can be greatly reduced.

FIG. 3C shows a circuit diagram for the ESD protection circuit 10 with reduced parasite capacitance according to still another embodiment of the present invention. The ESD protection circuit 10 shown in FIG. 3C comprises at least two unidirectional conduction units Dp1, Dp2 arranged between a positive voltage node Vd and an IO node PD of an integrated circuit, at least two unidirectional conduction units Dn1, Dn2 arranged between the IO node and a negative voltage node Vs, and a voltage tracking circuit 20′. As shown in this figure, the two unidirectional conduction units Dp1, Dp2 are for example two diodes Dp1, Dp2 in series connection and along the same polarity direction. Namely, the two diodes Dp1, Dp2 are in series connection between the positive voltage node Vd and the IO node PD for reverse bias, and a first connection node P1 is arranged between the two diodes Dp1, Dp2. The two unidirectional conduction units Dn1, Dn2 are for example two diodes Dn1, Dn2 in series connection and along the same polarity direction. Namely, the two diodes Dn1, Dn2 are in series connection between the IO node PD and the negative voltage node Vs for reverse bias, and a second connection node P2 is arranged between the two diodes Dn1, Dn2.

Moreover, the voltage tracking circuit 20′ comprises a first amplifier circuit 22A arranged between the IO node PD and the first connection node P1. The first amplifier circuit 22A is, for example, an amplifier circuit composed of voltage-division resistors with gain smaller than 1. For example, the gain of the first amplifier circuit 22A is larger than 0.9 and smaller than 1, namely, 0.9<(V_{PD}/V_{P1})<1. By the first amplifier circuit 22A, the diode Dp1 can be kept to be reversely biased and the voltage difference between the anode and the cathode thereof is nearly zero such that the parasite capacitance of the diode Dp1 can be greatly reduced. Besides, the voltage tracking circuit 20′ further comprises a second amplifier circuit 22B arranged between the IO node PD and the second connection node P2. The second amplifier circuit 22B is, for example, an amplifier circuit composed of voltage-division resistors with gain smaller than 1. For example, the gain of the second amplifier circuit 22B is larger than 0.9 and smaller than 1, namely, 0.9<(V_{P2}/V_{PD})<1. By the second amplifier circuit 22B, the diode Dn1 can be kept to be reversely biased and the voltage difference between the anode and the cathode thereof is nearly zero such that the parasite capacitance of the diode Dn1 can be greatly reduced.

The voltage tracking circuit 20′ shown in FIGS. 3A-3C can keep the voltages between the anode and the cathode of the diode Dp1 (and diode Dn1) to be substantial the same or close to each other, thus greatly reduce the parasite capacitance of the diode Dn1 (Dp1). The voltage tracking circuit 20′ can be realized by circuits other than those shown in FIGS. 3A-3C as long as the voltage tracking circuit 20′ can keep the voltages between the anode and the cathode of the diode Dp1 (and diode Dn1) to be substantial the same or close to each other (for example, the voltage difference is within 10% of the cathode voltage or within 10% of the anode voltage). These kinds of voltage tracking circuits 20′ can also reduce the parasite capacitance of the diode Dn1 (Dp1).

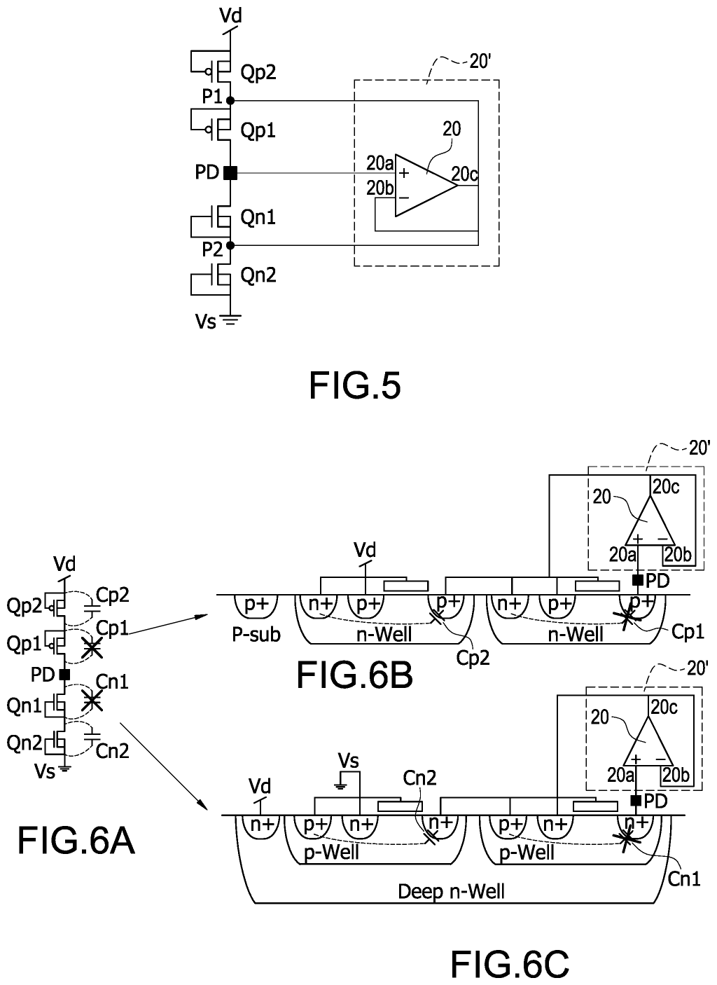

FIG. 5 shows a circuit diagram for the ESD protection circuit 10 with reduced parasite capacitance according to still another embodiment of the present invention. The embodiment shown in FIG. 5 is similar to that shown in FIG. 3A, however, the unidirectional conduction units Dp1, Dp2, Dn1, Dn2 in FIG. 3A are replaced by MOS transistors Qp1, Qp2, Qn1, Qn2 respectively in FIG. 5. Moreover, even though the voltage tracking circuit 20′ in FIG. 5 is depicted to be the voltage follower shown in FIG. 3A, the voltage tracking circuit 20′ in FIG. 5 can also be implemented as the non-inverting amplifier (gain is larger than 1 and smaller than 1.1) shown in FIG. 3B, or the division-resistor amplifier (gain is larger than 0.9 and smaller than 1) shown in FIG. 3C.

FIG. 6A is a schematic diagram showing the change of parasite capacitance in the ESD protection circuit 10 shown in FIG. 5 after the voltage tracking operation of the voltage tracking circuit 20′. Besides, FIGS. 6B and 6C respectively shows the semiconductor structures corresponding to upper portion and lower portion of FIG. 6A. As shown in FIG. 6A, due to the voltage tracking operation of the voltage tracking circuit 20′, the MOS transistor Qp1 has substantially no voltage difference between the drain and the source (namely, between the IO node PD and the first connection node P1) thereof; and accordingly, there is substantially no or nearly no parasite capacitance across the two channel terminals of the MOS transistor Qp1. Besides, due to the voltage tracking operation of the voltage tracking circuit 20′, the MOS transistor Qn1 has substantially no voltage difference between the drain and the source (namely, between the second connection node P2 and the IO node PD) thereof; and accordingly, there is substantially no or nearly no parasite capacitance across the two channel terminals of the MOS transistor Qn1. As clearly shown in FIG. 6A, a plurality of MOS transistors Qp1, Qp2 are serially connected between the positive voltage node Vd and the IO node PD. Namely, the parasite capacitances Cp1, Cp2 of those MOS transistors Qp1, Qp2 are also serially connected. If the capacitance of the parasite capacitance Cp1 is zero or nearly zero, the equivalent capacitance of the serially connected parasite capacitances Cp1, Cp2 is also zero or nearly zero. Besides, as also clearly shown in FIG. 6A, a plurality of MOS transistors Qn1, Qn2 are serially connected between the IO node PD and the negative voltage node Vs and. Namely, the parasite capacitances Cn1, Cn2 of those MOS transistors Qn1, Qn2 are also serially connected. If the capacitance of the parasite capacitance Cn1 is zero or nearly zero, the equivalent capacitance of the serially connected parasite capacitances Cn1, Cn2 is also zero or nearly zero. In other word, the ESD protection circuit 10 according to the present invention can greatly reduce the parasite capacitance thereof. Besides, even though FIG. 6A shows that two MOS transistors Qp1, Qp2 are serially connected between positive voltage node Vd and the IO node PD and two MOS transistors Qn1, Qn2 are serially connected between IO node PD and the negative voltage node Vs; according to the concept of the present invention, more MOS transistors can be serially connected between positive voltage node Vd and the IO node PD, and/or more MOS transistors can be serially connected between IO node PD and the negative voltage node Vs. The equivalent capacitance of the serially connected parasite capacitances is zero or nearly zero when one of the capacitances in the series is zero or nearly zero. Therefore, the ESD protection circuit 10 according to the present invention can be advantageously used in electronic device for sensing minute amount of capacitance change, such as electronic device with touch sensing function or hovering sensing function. The ESD protection circuit 10 according to the present invention not only provides ESD protection but also greatly reduces parasite capacitance.

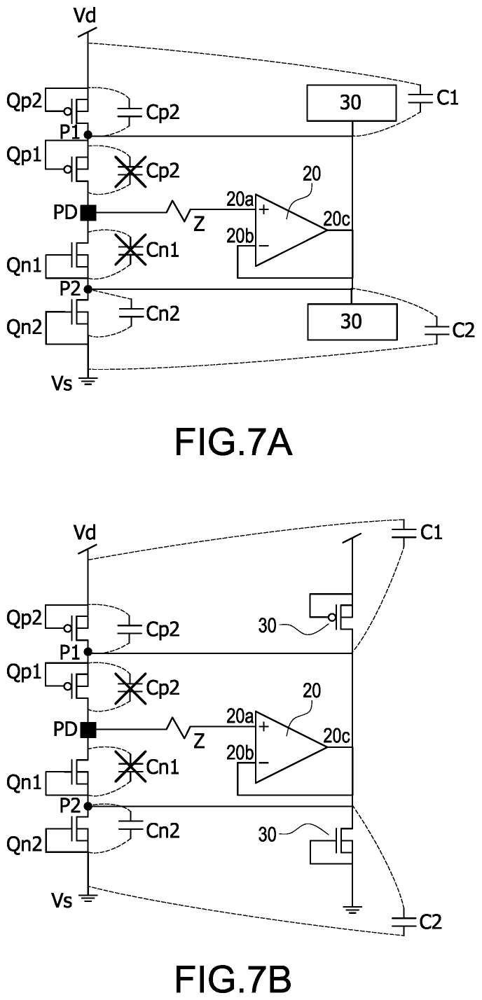

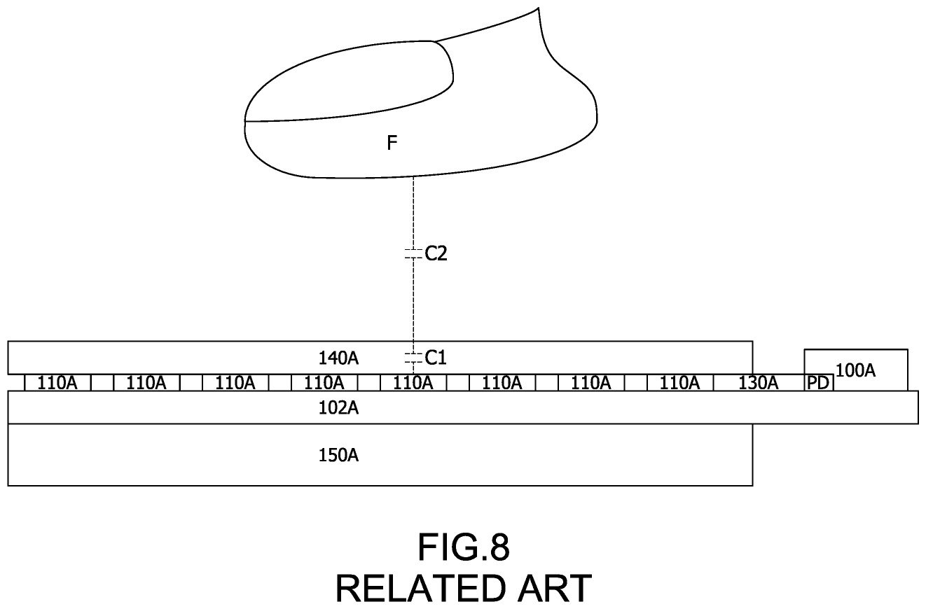

FIG. 7A shows a circuit diagram for the ESD protection circuit 10 with reduced parasite capacitance according to still another embodiment of the present invention. The embodiment shown in FIG. 7A is similar to that shown in FIG. 5, however, the embodiment shown in FIG. 7A further comprises auxiliary unidirectional conduction units 30 electrically connected to the first connection node P1 and the second connection node P2 respectively. The locations of the auxiliary unidirectional conduction units 30 may be closer to the operational amplifier 20 in comparison with the MOS transistors Qp1, Qp2, Qn1, Qn2 to provide further ESD protection effect. FIG. 7B is a more detailed circuit diagram corresponding to FIG. 7A, where the auxiliary unidirectional conduction unit 30 may be implemented by MOS transistor electrically connected to the positive voltage node Vd and the first connection node P1, and by MOS transistor electrically connected to the negative voltage node Vs and the second connection node P2. Similarly, the voltage follower composed of operational amplifier 20 can reduce or eliminate the parasite capacitances Cp1 and Cn1, thus also reduce or eliminate the effect of the parasite capacitances from the auxiliary unidirectional conduction units 30. The ESD protection circuit 10 with reduced parasite capacitance shown in FIGS. 7A and 7B not only provides ESD protection but also greatly reduces parasite capacitance to ensure the accuracy of touch sensing device or hovering sensing device.

To sum up, the ESD protection circuit with reduced parasite capacitance and method for reducing ESD parasite capacitance according to the present can reduce the parasite capacitance of the unidirectional conduction unit (such as diode or MOS transistor) by reducing the voltage difference between two terminals of the unidirectional conduction unit. The parasite capacitance associated with the ESD protection circuit can be greatly reduced. Therefore, the ESD protection circuit according to the present invention can be advantageously used in electronic device for sensing minute amount of capacitance change, such as electronic device with touch sensing function or hovering sensing function, thus greatly enhance the accuracy for touch sensing operation or hovering sensing operation.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. An electrostatic discharge (ESD) protection circuit with reduced parasite capacitance, the ESD protection circuit electrically connected to an IO node of an integrated circuit and comprising:
at least two unidirectional conduction units arranged between the IO node and a positive voltage node, wherein a first connection node is between the at least two unidirectional conduction units;
at least two unidirectional conduction units arranged between the IO node and a negative voltage node, wherein a second connection node is between the at least two unidirectional conduction units;
and a voltage tracking circuit, an input of the voltage tracking circuit connected to the IO node and an output of the voltage tracking circuit electrically connected to at least one of the first connection node and the second connection node such that the IO node and the first connection node have substantially the same voltage or the IO node and the second connection node have substantially the same voltage.

2. The ESD protection circuit in claim 1, wherein the unidirectional conduction units are diodes in reverse bias.

3. The ESD protection circuit in claim 1, wherein the unidirectional conduction units are transistors.

4. The ESD protection circuit in claim 3, wherein the transistors are MOS transistors.

5. The ESD protection circuit in claim 1, wherein the voltage tracking circuit is amplifier circuit.

6. The ESD protection circuit in claim 5, wherein the amplifier circuit has gain larger than 0.9 and smaller than 1.1.

7. The ESD protection circuit in claim 5, wherein the amplifier circuit is a voltage follower.

8. The ESD protection circuit in claim 1, wherein the IO node and the first connection node have voltage difference within 10% of a voltage at the IO node or a voltage at the first connection node, wherein the IO node and the second connection node have voltage difference within 10% of a voltage at the IO node or a voltage at the second connection node.

9. The ESD protection circuit in claim 8, wherein a parasite capacitance between the IO node and the first connection node is reduced or eliminated, or wherein a parasite capacitance between the IO node and the second connection node is reduced or eliminated.

10. A method for reducing electrostatic discharge (ESD) parasite capacitance, comprising:
(a) providing an ESD protection circuit for an IO node of an integrated circuit, the ESD protection circuit comprising:
at least two unidirectional conduction units arranged between the IO node and a positive voltage node, wherein a first connection node is between the at least two unidirectional conduction units;
at least two unidirectional conduction units arranged between the IO node and a negative voltage node, wherein a second connection node is between the at least two unidirectional conduction units;
(b) providing a voltage tracking circuit, connecting an input of the voltage tracking circuit to the IO node and connecting an output of the voltage tracking circuit to at least one of the first connection node and the second connection node such that the IO node and the first connection node have substantially the same voltage or the IO node and the second connection node have substantially the same voltage.

11. The method in claim 10, wherein the unidirectional conduction units are diodes in reverse bias.

12. The method in claim 10, wherein the unidirectional conduction units are transistors.

13. The method in claim 12, wherein the transistors are MOS transistors.

14. The method in claim 10, wherein the voltage tracking circuit is amplifier circuit.

15. The method in claim 14, wherein the amplifier circuit has gain larger than 0.9 and smaller than 1.1.

16. The method in claim 14, wherein the amplifier circuit is a voltage follower.

17. The method in claim 10, wherein the IO node and the first connection node have voltage difference within 10% of a voltage at the IO node or a voltage at the first connection node, wherein the IO node and the second connection node have voltage difference within 10% of a voltage at the IO node or a voltage at the second connection node.

18. The method in claim 17, wherein a parasite capacitance between the IO node and the first connection node is reduced or eliminated, or wherein a parasite capacitance between the IO node and the second connection node is reduced or eliminated.
